(19) United States
(12) Patent Application Publication
(10) Pub. No.: US 2026/0234802 A1
(43) Pub. Date: Aug. 13, 2026

(54) FURNACE TUBE FOR PLASMA ENHANCED THIN FILM DEPOSITION

(71) Applicants: ACM RESEARCH (SHANGHAI), INC., Shanghai (CN); ACM Research Korea CO., LTD., Icheon-si (KR); CleanChip Technologies Limited, Hong Kong (CN); ACM Research (Lingang), Inc., Shanghai (CN)

(72) Inventors: Hui Wang, Shanghai (CN); Jian Wang, Shanghai (CN); Shena Jia, Shanghai (CN); Hui Shen, Shanghai (CN); Dongcheng Zhou, Shanghai (CN); Dahai Zhang, Shanghai (CN); Ce Lv, Shanghai (CN); Gouqiang Chen, Shanghai (CN); Chi Ku Choi, Icheon-Si (KR); Jong Hyeok Cheon, Icheon-Si (KR); Ga Myeol Cheon, Icheon-Si (KR); Dong Keun Lee, Icheon-Si (KR)

(73) Assignees: ACM RESEARCH (SHANGHAI), INC., Shanghai (CN); ACM Research Korea CO., LTD., Icheon-si (KR); CleanChip Technologies Limited, Hong Kong (CN); ACM Research (Lingang), Inc., Shanghai (CN)

(21) Appl. No.: 19/156,750

(22) PCT Filed: Jan. 30, 2024
(86) PCT No.: PCT/CN2024/074744

§ 371 Date: Aug. 14, 2025

(30) Foreign Application Priority Data
Feb. 14, 2023 (CN) 202310112530.4

(51) Int. Cl. C23C 16/509; C23C 16/455

(52) U.S. Cl. CPC C23C 16/509; C23C 16/45536; C23C 16/45544; C23C 16/45591

(57) ABSTRACT

The present invention discloses a furnace tube for plasma enhanced thin film deposition, comprising: a process tube, having a reaction chamber and at least one ionization chamber constructed therein; a gas supply tube, for transporting the process gas to be ionized to the ionization chamber. After the process gas to be ionized is ionized in the ionization chamber, the ionized process gas enters the reaction chamber, so as to deposit a corresponding thin film on the surface of a substrate, or undergo an adsorption reaction to realize layer-by-layer growth of the thin film on the surface of the substrate. A first electrode and a second electrode are located in the process tube and at the middle position of the ionization chamber. Wherein, the first electrode and/or the second electrode are/is supported by a baffle plate, and one end of the baffle plate is connected to the corresponding electrode, and the other end of the baffle plate is connected to the inner wall of the ionization chamber, so that the process gas to be ionized passes between the first electrode and the second electrode. The present invention improves the ionization efficiency of the process gas.

### FIELD OF THE INVENTION

The present invention relates to the field of semiconductor processing equipment, and further to a furnace tube for plasma enhanced thin film deposition.

### BACKGROUND

The thin film deposition process is a key process in semiconductor manufacturing. Since the thin film is the functional material layer of the chip structure, the thin film will remain in the chip after the chip completes manufacturing, packaging and testing processes. The technical parameters of the thin film directly affect the performance of the chip. Due to the high precision of semiconductor device, the thin film is typically implemented by using the thin film deposition process. The thin film preparation process can be divided into Physical Vapor Deposition (PVD) and Chemical Vapor Deposition (CVD) according to the film formation method. Wherein, CVD refers to the process of depositing a solid film on the surface of the silicon wafer through a chemical reaction of gas mixing, and the use of CVD process equipment accounts for a higher proportion. The CVD process further includes Low Pressure Chemical Vapor Deposition (LPCVD), Plasma Enhanced Chemical Vapor Deposition (PECVD), Atomic Layer Deposition (ALD), and the like, wherein the ALD can also introduce the Plasma Enhanced Atomic Layer Deposition (PEALD).

The characteristic of PECVD is to ionize the gas containing the atoms that make up the film by microwaves or radio frequencies, and the plasma is formed locally. The plasma has strong chemical activity and is easy to react, and then the required thin film is deposited on the substrate. In the traditional CVD process, the chemical gas is continuously introduced into the vacuum chamber, so the deposition process is continuous. However, in the ALD process, different reaction precursors are alternately sent into the reaction chamber in the form of gas pulses, which is not a continuous process.

In the prior art, Plasma Enhanced Chemical Vapor Deposition (PECVD) and Atomic Layer Deposition (ALD) process equipment may adopt furnace tube type substrate processing apparatus.

As shown in FIG. 11(a), FIG. 11(a) is a schematic cross-sectional view of a substrate processing apparatus disclosed in Patent No. ZL03109343.4. The substrate processing apparatus comprises a reaction tube 1, a buffer chamber 2 disposed in the reaction tube 1, a gas nozzle 4 disposed in the buffer chamber 2, an electrode 5 for generating plasma, and a boat 6 for carrying wafers 7. Wherein, the gas nozzle input port 10 is used for introducing chemical gas. The chemical gas enters the buffer chamber 2 through the gas nozzle holes 9, and then is supplied to the wafers 7 through the buffer chamber holes 3 for thin film deposition. Finally, the inert gas and reaction residual gas are discharged from the exhaust port 8 of the reaction tube 1.

As shown in FIG. 11(b) and FIG. 11(c), FIG. 11(b) and FIG. 11(c) are schematic cross-sectional views of two different embodiments of FIG. 11(a). In these two embodiments, since there is a gap between the electrodes 5 and the side wall of the buffer chamber 2, after the chemical gas enters the buffer chamber 2 from the gas supply chamber, only a part of the chemical gas passes between the two electrodes 5 and flows out through the buffer chamber hole 3, and the other part of the chemical gas will directly flow out from the buffer chamber hole 3 along the gap between the electrodes 5 and the side wall of the buffer chamber 2. The chemical gas does not completely pass between the two electrodes 5, resulting in the chemical gas being only partially ionized and partially not ionized.

As shown in FIG. 11(d), FIG. 11(d) is a schematic cross-sectional view of the other embodiment of FIG. 11(a). In this embodiment, two electrodes 5 are disposed on both sides of the buffer chamber hole 3, and the electrodes 5 are close to the inner side wall surface of the buffer chamber 2, thereby defining the main flow direction of the gas. However, since the electrodes 5 are close to the inner side wall of the buffer chamber 2, the side of the electrodes 5 close to the inner side wall of the buffer chamber 2 is not effectively utilized, and the electric field generated on this side is absorbed by the inner side wall of the buffer chamber 2 and is not used for ionization of the chemical gas. And the distance between the gas nozzle hole 9 and the buffer chamber hole 3 is short, and the ionization area between the two electrodes is limited, resulting in the chemical gas flowing out from the buffer chamber hole 3 without being completely ionized after entering the buffer chamber 2 through the gas nozzle hole 9, thereby making the ionization efficiency of the chemical gas be low and increasing the power consumption.

### SUMMARY

In view of the above technical problems, an object of the present invention is to improve the ionization efficiency of the process gas in the furnace tube. In order to achieve the above object, the present invention provides a furnace tube for plasma enhanced thin film deposition.

In some embodiments, the furnace tube for plasma enhanced thin film deposition, comprising:
a process tube, including a reaction chamber capable of accommodating a plurality of substrates and at least one ionization chamber disposed along the stacking direction of the plurality of substrates, the ionization chamber being provided with a plurality of first gas holes communicating with the reaction chamber;
a gas supply tube, located in the ionization chamber, and provided with a plurality of second gas holes sequentially along the stacking direction of the plurality of substrates, the gas supply tube being used for transporting the process gas to be ionized and the process gas to be ionized being introduced into the ionization chamber through the second gas holes, after the process gas to be ionized being ionized in the ionization chamber, the ionized process gas being introduced into the reaction chamber through the first gas holes, so as to deposit a corresponding thin film on the surface of the substrate;
a first electrode and a second electrode, located in the process tube and at the middle position of the ionization chamber, and arranged along the stacking direction of the plurality of substrates;
wherein, the first electrode and/or the second electrode are/is supported by a baffle plate, one end of each baffle plate is connected to the corresponding electrode, and the other end of each baffle plate is connected to the inner wall of the ionization chamber, so that the process gas to be ionized passes between the first electrode and the second electrode to improve the ionization efficiency of the process gas, and the first gas holes are located on the vertical line of the line connecting between the first electrode and the second electrode.

In some embodiments, the furnace tube for plasma enhanced thin film deposition, comprising:
a process tube, including a reaction chamber capable of accommodating a plurality of substrates and at least one ionization chamber disposed in the stacking direction along the plurality of substrates, the ionization chamber being provided with a plurality of first gas holes communicating with the reaction chamber;
a gas supply tube, located in the ionization chamber, and provided with a plurality of second gas holes sequentially along the stacking direction of the plurality of substrates, the gas supply tube being used for transporting the process gas to be ionized and the process gas to be ionized being introduced into the ionization chamber through the second gas holes, after the process gas to be ionized being ionized in the ionization chamber, the ionized process gas being introduced into the reaction chamber through the first gas holes, so as to deposit a corresponding thin film on the surface of the substrate;
a first electrode and a second electrode, located in the process tube, and arranged along the stacking direction of the plurality of substrates, the first electrode and/or the second electrode being located on the side wall of the ionization chamber, and a part of the electrode located on the side wall of the ionization chamber being located inside the ionization chamber, and the other part being located outside the ionization chamber.

Compared with the prior art, on one hand, the present invention constructs a baffle plate between the electrodes and the inner wall of the ionization chamber, so that the process gas passes between the two electrodes, and prevents the process gas from directly escaping from the ionization chamber through the gap between the electrodes and the inner wall of the ionization chamber without passing between the two electrodes, thereby improving the ionization efficiency of the process gas and maximizing the ionization of the process gas; On the other hand, by constructing at least one electrode on the side wall of the ionization chamber, and a part of the electrode constructed on the side wall of the ionization chamber is located inside the ionization chamber and the other part is located outside the ionization chamber, during the ionization of process gas, the electrodes generate the electric field only in the part located inside the ionization chamber and does not generate the electric field in the part located outside the ionization chamber, so that the electric field generated by the electrodes is entirely used for ionization of the process gas and is not absorbed by the side wall of the ionization chamber, thereby reducing the power consumption of the apparatus.

### BRIEF DESCRIPTION OF THE DRAWINGS

Hereinafter, the above-described features, technical features, advantages and embodiments of the present invention will be further described in a clear and easily understood manner with reference to the accompanying drawings and preferred embodiments.

FIGS. 1(a)-1(e) are schematic cross-sectional structural views of a set of embodiments of furnace tubes of the present invention;

FIGS. 2(a)-2(e) are schematic cross-sectional structural views of another set of embodiments of furnace tubes of the present invention;

FIGS. 3(a)-3(e) are schematic cross-sectional structural views of another set of embodiments of furnace tubes of the present invention;

FIGS. 4(a)-4(d) are schematic cross-sectional structural views of another set of embodiments of furnace tubes of the present invention;

FIGS. 5(a)-5(e) are schematic cross-sectional structural views of another set of embodiments of furnace tubes of the present invention;

FIGS. 6(a)-6(d) are schematic cross-sectional structural views of another set of embodiments of furnace tubes of the present invention;

FIGS. 7(a)-7(e) are schematic cross-sectional structural views of another set of embodiments of furnace tubes of the present invention;

FIGS. 8(a)-8(b) are schematic cross-sectional structural views of another set of embodiments of furnace tubes of the present invention;

FIGS. 9(a)-9(c) are schematic cross-sectional structural views of another set of embodiments of furnace tubes of the present invention;

FIGS. 10(a)-10(b) are schematic sectional views of the three-dimensional structures of a set of embodiments of furnace tubes of the present invention;

FIGS. 11(a) to 11(d) are schematic views of a set of structures of a substrate processing apparatus according to the background of the present invention.

### EMBODIMENTS OF THE INVENTION

In order to more clearly explain the embodiments of the present invention or the technical solutions in the prior art, specific embodiments of the present invention will be described below with reference to the accompanying drawings. It is obvious that the drawings in the following description are only some embodiments of the present invention, and other drawings and other embodiments can be obtained from these drawings without making creative efforts to those of ordinary skill in the art.

For the sake of simplicity of the drawings, only parts related to the invention are schematically shown in the drawings, and the parts do not represent the actual structures thereof as products. In addition, in order to make the drawings simple and easy to understand, in some drawings, only one of the components having the same structure or function is schematically illustrated or only one of the components is designated. In the present specification, “one” means not only “only one”, but also “more than one”.

In the present specification, it should be noted that unless otherwise specified and defined, the terms “mounted”, “connected” and “communicated” are to be understood broadly, for example, fixedly connected, detachably connected, or integrally connected; The connection may be mechanical or electrical; It can be directly connected, indirectly connected through an intermediate medium, and it can be the internal communication of two elements. For those of ordinary skill in the art, the specific meanings of the above terms in the present invention can be understood according to the specific circumstances.

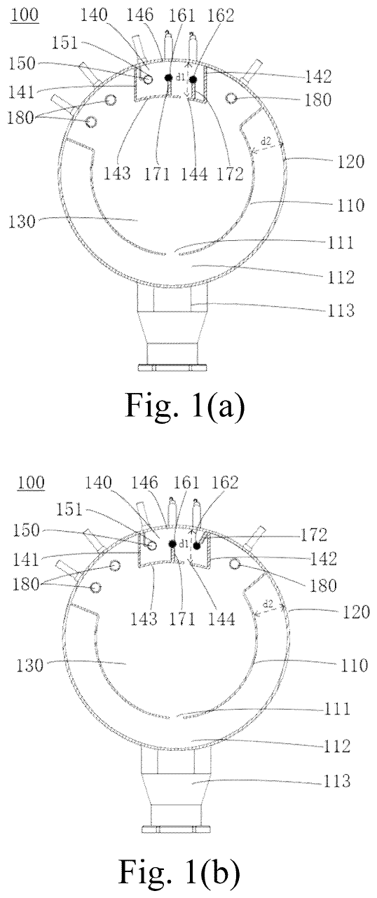

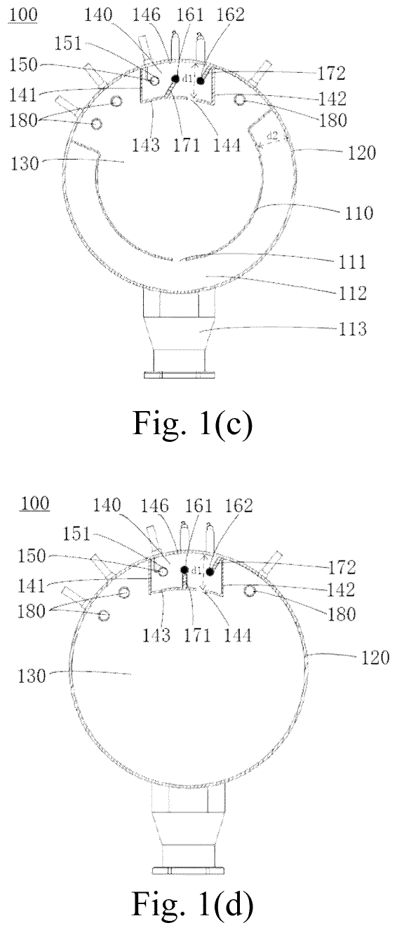

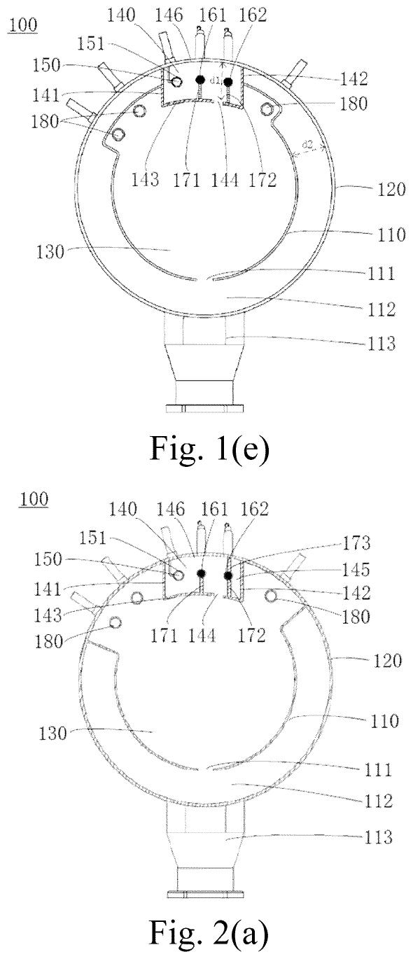

As shown in FIGS. 1(a) to 10(b), the present invention discloses a furnace tube 100 having various embodiments, and the main difference of the various embodiments is the internal structure of the ionization chamber 140 and the arrangement positions of electrodes (such as the first electrode 161 and the second electrode 162) and the gas supply tube 150 in the ionization chamber 140. With respect to the overall structure of the furnace tube 100, various embodiments adopt similar structures, including at least one process tube 120 that processes the substrates using the Plasma Enhanced Chemical Vapor Deposition (PECVD) or Atomic Layer Deposition (ALD) process and a power supply unit that supplies power to electrodes (such as the first electrode 161 and the second electrode 162).

Specifically, inside the process tube 120, a reaction chamber 130 for performing process treatment on the substrates, an ionization chamber 140 for ionizing the process gas, a gas supply tube 150 for supplying the process gas to be ionized to the inside of the ionization chamber 140, a plurality of additional gas supply tubes 180 for directly supplying the process gas or inert gas to the inside of the reaction chamber 130, and a heater (not shown in the figure) for heating the process tube 120 are provided. Below the reaction chamber 130, a wafer boat for carrying the substrates and a lifting mechanism for moving the wafer boat up and down are provided. The above-described process tube 120 and the reaction chamber 130 and the ionization chamber 140 inside the process tube 120 are all of vertical hollow cylindrical structures, and the bottom of the reaction chamber 130 is provided with an opening for the wafer boat to enter and exit, so that the wafer boat can move up and down under the action of the lifting mechanism, and the substrates carried by the wafer boat can move into or out of the reaction chamber 130 with the wafer boat.

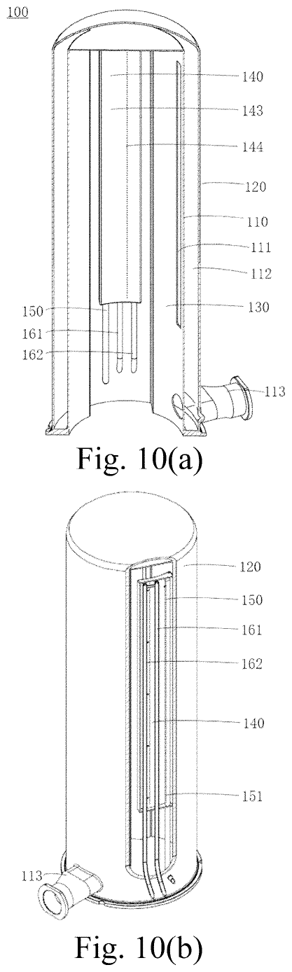

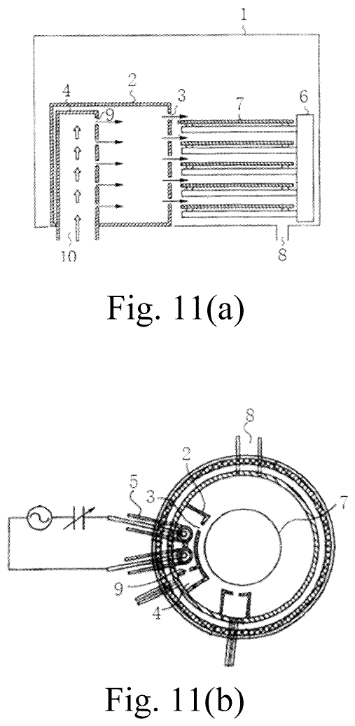

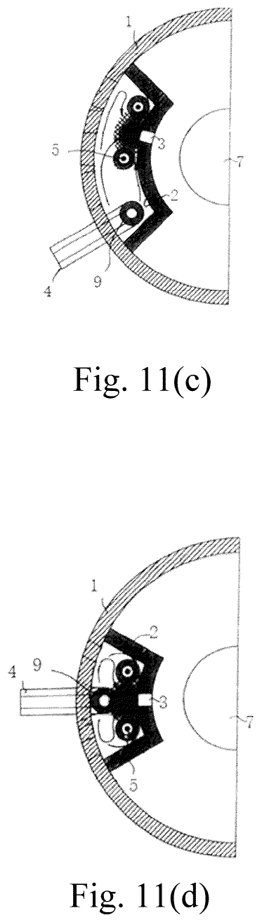

FIG. 10(a) is a sectional view of the furnace tube 100 along the axial direction, and FIG. 10(b) is a longitudinal sectional view of the furnace tube 100 outside the ionization chamber 140. In the ionization chamber 140, at least a pair of electrodes (such as the first electrode 161 and the second electrode 162) and a gas supply tube 150 are provided, and the first electrode 161, the second electrode 162 and the gas supply tube 150 are all fixed in the ionization chamber 140 along the vertical direction. Wherein, the plurality of first gas holes 144 in communication with the reaction chamber 130 are sequentially set along the vertical direction or along the stacking direction of the plurality of substrates. The first electrode 161 and the second electrode 162 are connected to the power supply unit to generate a high-frequency electric field that ionizes the process gas, and the ionization density between the first electrode 161 and the second electrode 162 is the highest. The distance between the first electrode 161 and the second electrode 162 is preferably in the range of 15 mm-60 mm, and the ionization power is preferably in the range of 100-2000 W. The plurality of second gas holes 151 are sequentially set on the gas supply tube 150 along the vertical direction or along the stacking direction of the plurality of substrates, and the bottom of the gas supply tube 150 is connected to an external gas source for transporting the process gas to be ionized into the ionization chamber 140 through the second gas holes 151. After the above-described process gas to be ionized enters the ionization chamber 140, the process gas is ionized by the first electrode 161 and the second electrode 162, and then enters the reaction chamber 130 through the first gas holes 144 to deposit the corresponding thin film on the surface of the substrates, or an adsorption reaction occurs to realize layer-by-layer growth of the thin film on the surface of the substrates. The cross-sectional shape of the ionization chamber 140 is not limited to the fan-ring shape provided in the drawings of each embodiment, and regular or irregular closed patterns such as semicircle, triangle and rectangle may be selected according to the actual situation. The gas flow rate in the gas supply tube 150 is preferably in the range of 1 L/min to 30 L/min. The ratio range of the flow area or cross-sectional area of the gas supply tube 150 to the second gas holes 151 is preferably 1: (0.21-0.48). By limiting the ratio range of the flow area or cross-sectional area of the gas supply tube 150 to the second gas holes 151 within the above range, the flow rate of the process gas in the gas supply tube 150 and the supply rate of the second gas holes 151 into the ionization chamber 140 can be effectively controlled, so that the process gas has sufficient ionization time in the ionization chamber 140.

In addition, as shown in FIG. 1(a), FIG. 1(b), FIG. 1(c), FIG. 1(e), etc., some embodiments of the present invention adopt a multi-tube furnace tube structure. In these embodiments, the process tube 120 further comprises an inner tube 110 having the fan ring shape, and an inner arc part of the inner tube 110 and the process tube 120 form a concentric circle structure, and the plurality of substrates are located in the inner tube 110. A hollow suction chamber 112 is formed between the inner tube 110 and the process tube 120, and a plurality of third gas holes 111 in communication with the reaction chamber 130 are sequentially set on the inner tube 110 along the vertical direction or along the stacking direction of the plurality of substrates. The third gas holes 111 are disposed opposite to the ionization chamber 140, and the third gas holes 111 are in communication with the suction chamber 112. The exhaust tubes 113 in communication with the suction chamber 112 are provided at the bottom of the process tube 120, and the exhaust tubes 113 are provided opposite to the ionization chamber 140. The radial distance d1 between the first gas holes 144 and the inner wall of the process tube 120 is not less than the radial distance d2 between the inner tube 110 and the inner wall of the process tube 120, so that the first gas holes 144 can be closer to the plurality of substrates, and the probability that the process gas reaches the surface of the substrates is increased.

As shown in FIG. 1(d), another embodiment of the present invention adopts a single-tube furnace tube structure, and in this embodiment, no inner tube 110 is provided in the process tube 120. It should be noted that the internal structure of the ionization chamber 140 disclosed in each embodiment of the present invention is not limited to the type of furnace tube, and different ionization chambers 140 may be adapted to either a single-tube furnace tube structure or a multi-tube furnace tube structure without departing from the principles of the present invention.

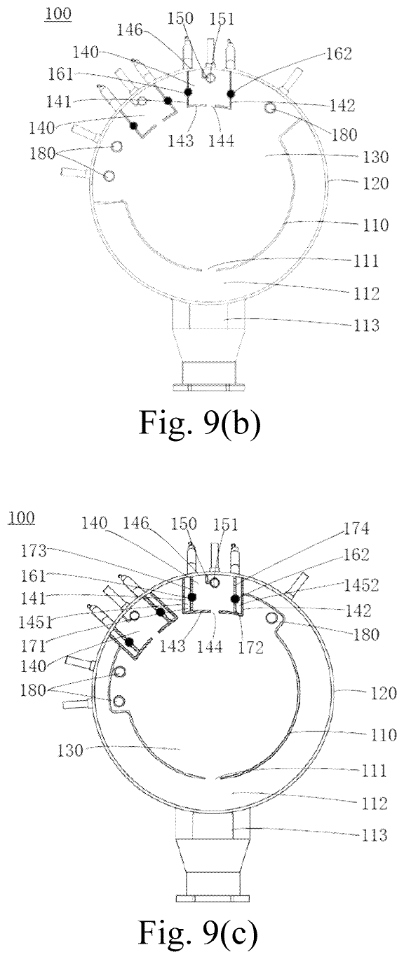

In addition, as shown in FIGS. 9(a), 9(b) and 9(c), some embodiments of the present invention adopt the structure of a plurality of ionization chambers 140. In these embodiments, the internal structure form of the ionization chamber 140 of any embodiment of the present invention can be selected according to actual needs, and the internal structures of different ionization chambers 140 may be the same or different. In addition, as shown in FIGS. 1(a), 1(b) and 1(c), in some embodiments of the present invention in which a multi-tube furnace tube structure is adopted, the inner tube 110 and the process tube 120 can be fixedly connected by a radial wall body, and the additional gas supply tubes 180 are located near the ionization chamber 140 and are provided close to the inner wall of the process tube 120. As shown in FIG. 1(e), in another embodiment of the present invention using the multi-tube furnace tube structure, the inner tube 110 may also be fixed to the left side wall 141 and the right side wall 142 of the ionization chamber 140, and the additional gas supply tubes 180 are located near the ionization chamber 140 and are provided close to the inner wall of the inner tube 110. The radius of the inner tube 110 at the position of the additional gas supply tubes 180 is larger than the radius of the inner tube 110 at other positions, and the additional gas supply tubes 180 and the first gas holes 144 are approximately located on the same circular arc line, so that the distance between the additional gas supply tubes 180 and the plurality of substrates is approximately equal to the distance between the first gas holes 144 and the plurality of substrates.

Besides, it should be noted that the first electrode 161 and the second electrode 162 in the present invention are located at the middle position of the ionization chamber 140, which means that the first electrode 161 and the second electrode 162 are located at the middle position between the first inner side wall 146 and the second inner side wall 143 of the ionization chamber 140. The first electrode 161 is located at the middle position between the left side wall 141 and the right side wall 142, or the second electrode 161 are located at the middle position between the left side wall 141 and the right side wall 142, or both the first electrode 161 and the second electrode 162 are located at the middle position between the left side wall 141 and the right side wall 142.

For example, during an Atomic Layer Deposition (ALD) process, the first process gas (e.g., dichlorosilane) is introduced into the process tube 120 from the additional gas supply tubes 180. After the adsorption between the first process gas and the surface of substrates reaches saturation, the inert gas is introduced into the process tube 120 through the additional gas supply tubes 180. The inert gas extracts the excess first process gas in the process tube 120 out of the process tube 120 from the exhaust tubes 113 through the third gas holes 111, and only the part adsorbed on the surface of substrates is retained. Then, the second process gas (e.g., ammonia gas) enters the ionization chamber 140 through the gas supply tube 150 and through the second gas holes 151 in the ionization chamber 140, and the second process gas completes the ionization under the action of the first electrode 161 and the second electrode 162, and enters the reaction chamber 130 through the first gas holes 144 to react with the first process gas adsorbed on the surface of substrates to form the thin film (e.g., silicon nitride thin film). After the complete adsorption reaction with the first process gas, the introduction of the second process gas into the ionization chamber 140 is stopped, and the inert gas is again introduced into the process tube 120 through the additional gas supply tubes 180, so as to purge the by-product of the reaction on the surface of substrates and discharge the by-product through the exhaust tubes 113, thereby completing the primary atomic layer deposition. In the semiconductor process, the above-described steps may be cycled as many times as necessary to form the thin film of desired thickness on the surface of substrates.

Hereinafter, each embodiment of the present invention will be described one by one with reference to FIGS. 1(a) to 9(c).

### Embodiment 1

As shown in FIG. 1(a), in the first embodiment of the present invention, the present embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

In the present embodiment, the ionization chamber 140 comprises a left side wall 141, a right side wall 142, a first inner side wall 146 and a second inner side wall 143. The first inner side wall 146 may be constituted by the inner wall of the process tube 120 between the left side wall 141 and the right side wall 142. Wherein, one end of the left side wall 141 and the right side wall 142 is fixedly connected to the first inner side wall 146, and the other end is respectively connected to both ends of the second inner side wall 143. The second inner side wall 143 corresponds to the first inner side wall 146, and the second inner side wall 143 is located within the radius range of the inner tube 110.

Inside the ionization chamber 140, the first electrode 161 and the second electrode 162 are sequentially located on the same arc line, the center of the arc is the same as the center of the process tube 120, and the radius of the arc is located between the radius ranges of the process tube 120 and the inner tube 110. The gas supply tube 150 is disposed close to the left side wall 141, and the gas supply tube 150 is disposed on the same side of the first electrode 161 and the second electrode 162. The first electrode 161 is disposed at the middle position between the left side wall 141 and the right side wall 142, and the second electrode 162 is disposed close to the right side wall 142. The first gas holes 144 are set on the vertical line of the line connecting between the first electrode 161 and the second electrode 162.

In addition, the baffle plates (171, 172) are connected between the first electrode 161 and the second electrode 162 and the second inner side wall 143 respectively. Specifically, the first electrode 161 is connected to the second inner side wall 143 on the left side of the first gas holes 144 with a first baffle plate 171, the second electrode 162 is connected to the second inner side wall 143 on the right side of the first gas holes 144 with a second baffle plate 172. The first baffle plate 171 extends from the bottom of the ionization chamber 140 to the top of the ionization chamber 140 along the length direction of the first electrode 161, and the second baffle plate 172 extends from the bottom of the ionization chamber 140 to the top of the ionization chamber 140 along the length direction of the second electrode 162. In the vertical direction, the upper and lower ends of the first electrode 161 and the second electrode 162 are fixed to the top and the bottom of the ionization chamber 140 respectively; In the horizontal direction, the first electrode 161 is supported by the first baffle plate 171, and the second electrode 162 is supported by the second baffle plate 172. The first baffle plate 171 and the second baffle plate 172 are parallel to each other. A flow channel of the process gas is formed between the first electrode 161 and the second electrode 162, so that the process gas passes through the ionization area between the first electrode 161 and the second electrode 162. And the process gas is prevented from directly escaping from the ionization chamber 140 through the gap between the first electrode 161 or the second electrode 162 and the inner wall of the ionization chamber 140 without passing between the first electrode 161 and the second electrode 162, thereby improving the ionization efficiency of the process gas. The baffle plates (171, 172) are made of an insulating material, preferably the quartz material.

In the present embodiment, the lifting mechanism lifts the wafer boat carrying the plurality of substrates into the reaction chamber 130, and the process gas to be ionized enters the ionization chamber 140 through the gas supply tube 150 and the second gas holes 151. In the ionization chamber 140, the first baffle plate 171 blocks the flow of the process gas to be ionized along the space between the second inner side wall 143 and the first electrode 161, and the second baffle plate 172 blocks the flow of the process gas to be ionized along the space between the second inner side wall 143 and the second electrode 162, so that the process gas to be ionized must pass between the first electrode 161 and the second electrode 162 and between the first baffle plate 171 and the second baffle plate 172 before entering the reaction chamber 130 through the first gas holes 144, thereby improving the ionization efficiency of the process gas. The ionized process gas enters the reaction chamber 130 through the respective first gas holes 144 and is uniformly supplied to the respective substrates carried by the wafer boat. When the gas in the reaction chamber 130 is replaced or discharged, the original gas in the reaction chamber 130 is firstly pumped from the third gas holes 111 to the suction chamber 112, and then is pumped out of the process tube 120 by the exhaust tubes 113.

### Embodiment 2

As shown in FIG. 1(b), in the second embodiment of the present invention, the present embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between this embodiment and the first embodiment is only in the placement position of the second baffle plate 172. In the first embodiment, the second baffle plate 172 is provided between the second electrode 162 and the second inner side wall 143 on the right side of the first gas holes 144. In the present embodiment, one side of the second baffle plate 172 is connected to the second electrode 162, and the other side is connected to the connection position between the right side wall 142 and the first inner side wall 146, so that the second baffle plate 172 forms an acute angle with the right side wall 142.

In the present embodiment, the first baffle plate 171 blocks the flow of the process gas to be ionized along the space between the second inner side wall 143 and the first electrode 161, and the second baffle plate 172 blocks the flow of the process gas to be ionized along the space between the right side wall 142 and the second electrode 162, so that the process gas to be ionized must pass through the ionization area between the first electrode 161 and the second electrode 162 and the flow channel between the first baffle plate 171 and the second baffle plate 172 before entering the reaction chamber 130 through the first gas holes 144. The process gas is prevented from directly escaping out of the ionization chamber 140 through the gap between the first electrode 161 or the second electrode 162 and the inner wall of the ionization chamber 140 without passing between the first electrode 161 and the second electrode 162, thereby improving the ionization efficiency of the process gas.

### Embodiment 3

As shown in FIG. 1(c), in the third embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between this embodiment and the first embodiment is only in the placement positions of the first baffle plate 171 and the second baffle plate 172. In the first embodiment, the first baffle plate 171 is perpendicular to the second inner side wall 143, and the second baffle plate 172 is disposed between the second electrode 162 and the second inner side wall 143 on the right side of the first gas holes 144. In the present embodiment, one side of the first baffle plate 171 is connected to the first electrode 161, the other side of the first baffle plate 171 is connected to the second inner side wall 143, and the connection position between the first baffle plate 171 and the second inner side wall 143 is biased toward the gas supply tube 150, so that the first baffle plate 171 forms an acute angle with the second inner side wall 143; One side of the second baffle plate 172 is connected to the second electrode 162, and the other side is connected to the connection position of the right side wall 142 and the first inner side wall 146, so that the second baffle plate 172 forms the acute angle with the right side wall 142. The first baffle plate 171 is parallel to the extension line of the second baffle plate 172.

In this embodiment, the first baffle plate 171 blocks the flow of the process gas to be ionized along the space between the second inner side wall 143 and the first electrode 161, the second baffle plate 172 blocks the flow of the process gas to be ionized along the space between the right side wall 142 and the second electrode 162. And since the first baffle plate 171 is inclined, on the one hand, the process gas to be ionized provided by the gas supply tube 150 tends to flow between the first electrode 161 and the first inner side wall 146. On the other hand, the influence of the first baffle plate 171 on the ionization area between the first electrode 161 and the second electrode 162 is reduced, and the space of ionization area between the first electrode 161 and the second electrode 162 is increased, so that the process gas to be ionized must pass through the ionization area between the first electrode 161 and the second electrode 162 and the flow channel between the first baffle plate 171 and the second baffle plate 172 before entering the reaction chamber 130 through the first gas holes 144. The process gas is prevented from directly escaping out of the ionization chamber 140 through the gap between the first electrode 161 or the second electrode 162 and the inner wall of the ionization chamber 140 without passing between the first electrode 161 and the second electrode 162, thereby improving the ionization efficiency of the process gas.

### Embodiment 4

As shown in FIG. 1(d), in the fourth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between the present embodiment and the second embodiment is only that the inner tube 110 is not provided inside the process tube 120 of the present embodiment, and the inner tube 110 is provided inside the process tube 120 of the second embodiment as a multi-tube furnace tube, and other structures are consistent with the structures of the second embodiment, and will not be repeated here.

In addition, as shown in FIG. 1(e), the inner tube 110 may be fixed to the left side wall 141 and the right side wall 142 of the ionization chamber 140, and the additional gas supply tubes 180 may be located near the ionization chamber 140 and are provided close to the inner wall of the inner tube 110. The radius of the inner tube 110 at the position of the additional gas supply tubes 180 is larger than the radius of the inner tube 110 at other positions. The additional gas supply tubes 180 are located within the inner tube 110 and approximately on the same arc line as the first gas holes 144, such that the distance from the additional gas supply tubes 180 to the plurality of substrates is approximately equal to the distance from the first gas holes 144 to the plurality of substrates.

### Embodiment 5

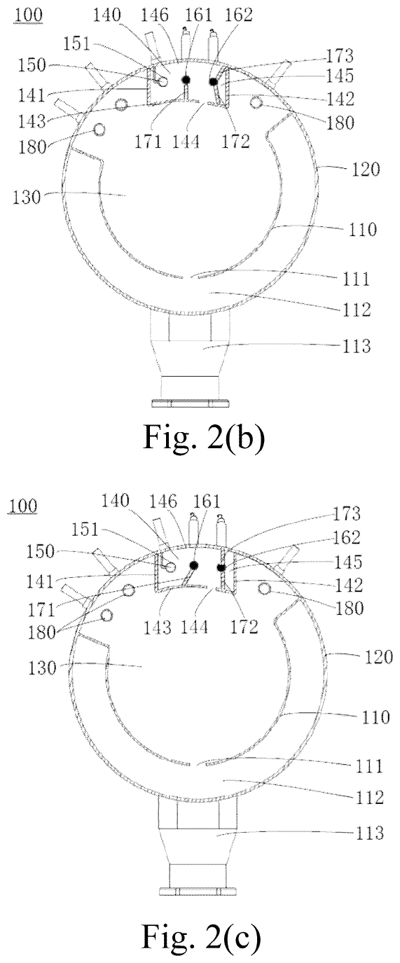

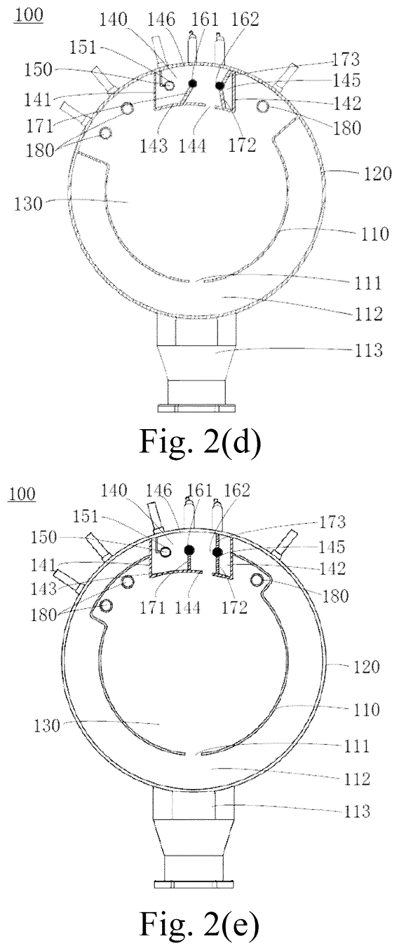

As shown in FIG. 2(a), in the fifth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The only difference between this embodiment and the first embodiment is that the third baffle plate 173 is added in this embodiment. In the first embodiment, the first electrode 161 is connected to the second inner side wall 143 on the left side of the first gas holes 144 with a first baffle plate 171, the second electrode 162 is connected to the second inner side wall 143 on the right side of the first gas holes 144 with a second baffle plate 172. And no baffle plate is provided between the second electrode 162 and the first inner side wall 146. In the present embodiment, the first baffle plate 171 and the second baffle plate 172 are placed at the same position as in the first embodiment, and the second electrode 162 and the first inner side wall 146 are connected to the third baffle plate 173. The above-described third baffle plate 173 is located on the extension line of the second baffle plate 172, and a vacuum chamber 145 is provided between the right side of the second baffle plate 172 and the third baffle plate 173 and the right side wall 142 of the ionization chamber 140. The second electrode 162 is located partially within the ionization chamber 140 on the left side of the second baffle plate 172 and the third baffle plate 173, and partially within the vacuum chamber 145 on the right side of the second baffle plate 172 and the third baffle plate 173. The vacuum degree in the vacuum chamber 145 can be independently controlled, and the vacuum degree in the vacuum chamber 145 is not affected by the gas flow in the ionization chamber 140 and the reaction chamber 130. When the inside of the vacuum chamber 145 is maintained at atmospheric pressure or low vacuum, the second electrode 162 does not generate an electric field in the vacuum chamber 145, so that the electric field generated by the second electrode 162 and the first electrode 161 is always stably concentrated between the second electrode 162 and the first electrode 161, and the vacuum degree inside the vacuum chamber 145 is preferably 0.005 torr-10 torr.

In the present embodiment, the first baffle plate 171 blocks the flow of the process gas to be ionized along the space between the second inner side wall 143 and the first electrode 161, the second baffle plate 172 blocks the flow of the process gas to be ionized along the space between the right side wall 142 and the second electrode 162, and the third baffle plate 173 blocks the flow of the process gas to be ionized along the space between the first inner side wall 146 and the second electrode 162. Hence, the process gas to be ionized must pass through the ionization area between the first electrode 161 and the second electrode 162 and the flow channel between the first baffle plate 171 and the second baffle plate 172 before entering the reaction chamber 130 through the first gas holes 144, thereby improving the ionization efficiency of the process gas. Besides, since the second electrode 162 is located locally in the vacuum chamber 145, the second electrode 162 generates an electric field only in the ionization chamber 140 on the left side of the second baffle plate 172 and the third baffle plate 173, and does not generate an electric field in the vacuum chamber 145, thereby playing a role in saving power.

### Embodiment 6

As shown in FIG. 2(b), in the sixth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between this embodiment and the fifth embodiment is only in the placement positions of the second baffle plate 172 and the third baffle 173. In the first embodiment, the second baffle plate 172 and the third baffle plate 173 are respectively parallel to the right side wall 142. In this embodiment, the connection position of the second baffle plate 172 and the second inner side wall 143 is biased toward the right side wall 142, such that the second baffle plate 172 forms the acute angle with the right side wall 142; The connection position of the third baffle plate 173 with the first inner side wall 146 is biased toward the right side wall 142, such that the third baffle plate 173 forms an acute angle with the right side wall 142.

In the present embodiment, the first baffle plate 171 blocks the flow of the process gas to be ionized along the space between the second inner side wall 143 and the first electrode 161, the second baffle plate 172 blocks the flow of the process gas to be ionized along the space between the right side wall 142 and the second electrode 162, and the third baffle plate 173 blocks the flow of the process gas to be ionized along the space between the first inner side wall 146 and the second electrode 162. And since the third baffle plate 173 is inclined, the process gas to be ionized tends to flow between the first baffle plate 171 and the second baffle plate 172. Hence, the process gas to be ionized must pass through the ionization area between the first electrode 161 and the second electrode 162 and the flow channel between the first baffle plate 171 and the second baffle plate 172 before entering the reaction chamber 130 through the first gas holes 144, thereby improving the ionization efficiency of the process gas. And since the second baffle plate 172 and the third baffle plate 173 are both inclined toward the right side wall 142, the part of the second electrode 162 exposed within the ionization chamber 140 on the left side of the second baffle plate 172 and the third baffle plate 173 is more than the part located within the vacuum chamber 145, thereby increasing the ionization area of the second electrode 162 within the ionization chamber 140. In addition, since the second electrode 162 is partially located in the ionization chamber 140 and the other part is located in the vacuum chamber 145, the second electrode 162 will generates an electric field only in the ionization chamber 140 on the left side of the second baffle plate 172 and the third baffle plate 173, and will not generate an electric field in the vacuum chamber 145, so that the electric field generated by the second electrode 162 is entirely used for ionization of the process gas and is not absorbed by the inner wall of the ionization chamber 140, thereby playing a role in saving power.

### Embodiment 7

As shown in FIG. 2(c), in the seventh embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between this embodiment and the fifth embodiment is only in the placement position of the first baffle plate 171. In the fifth embodiment, the first baffle plate 171 is disposed perpendicular to the second inner side wall 143. In the present embodiment, the connection position of the first baffle plate 171 and the second inner side wall 143 is biased toward the left side wall 141, such that the first baffle plate 171 forms the acute angle with the second inner side wall 143.

In this embodiment, the first baffle plate 171 blocks the flow of the process gas to be ionized along the space between the second inner side wall 143 and the first electrode 161, the second baffle plate 172 blocks the flow of the process gas to be ionized along the space between the right side wall 142 and the second electrode 162, and the third baffle plate 173 blocks the flow of the process gas to be ionized along the space between the first inner side wall 146 and the second electrode 162. And since the first baffle plate 171 is inclined, the process gas to be ionized tends to flow between the first baffle plate 171 and the second baffle plate 172, so that the process gas to be ionized must pass through the ionization region between the first electrode 161 and the second electrode 162 and the flow channel between the first baffle plate 171 and the second baffle plate 172 before entering the reaction chamber 130 through the first gas holes 144. The process gas is prevented from directly escaping out of the ionization chamber 140 through the gap between the first electrode 161 or the second electrode 162 and the inner wall of the ionization chamber 140 without passing between the first electrode 161 and the second electrode 162, thereby improving the ionization efficiency of the process gas. And since the connection position between the first baffle plate 171 and the second inner side wall 143 is biased toward the left side wall 141, the influence of the first baffle plate 171 on the ionization region between the first electrode 161 and the second electrode 162 is reduced, and the ionization area space between the first electrode 161 and the second electrode 162 is increased. In addition, since the second electrode 162 is partially located in the ionization chamber 140 and the other part is located in the vacuum chamber 145, the second electrode 162 will generate an electric field only in the ionization chamber 140 on the left side of the second baffle plate 172 and the third baffle plate 173, and will not generate an electric field in the vacuum chamber 145, so that the electric field generated by the second electrode 162 is entirely used for ionization of the process gas and is not absorbed by the inner wall of the ionization chamber 140, thereby playing a role in saving power.

### Embodiment 8

As shown in FIG. 2(d), in the eighth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between this embodiment and the sixth embodiment is only in the placement position of the first baffle plate 171. In the sixth embodiment, the first baffle plate 171 is disposed perpendicular to the second inner side wall 143. In the present embodiment, the connection position of the first baffle plate 171 and the second inner side wall 143 is biased toward the left side wall 141, such that the first baffle plate 171 forms the acute angle with the second inner side wall 143.

In this embodiment, the first baffle plate 171 blocks the flow of the process gas to be ionized along the space between the second inner side wall 143 and the first electrode 161, the second baffle plate 172 blocks the flow of the process gas to be ionized along the space between the right side wall 142 and the second electrode 162, and the third baffle plate 173 blocks the flow of the process gas to be ionized along the space between the first inner side wall 146 and the second electrode 162. And since the first baffle plate 171 is inclined, the process gas to be ionized tends to flow between the first baffle plate 171 and the second electrode 162. Hence, the process gas to be ionized must pass through the ionization area between the first electrode 161 and the second electrode 162 and the flow channel between the first baffle plate 171 and the second baffle plate 172 before entering the reaction chamber 130 through the first gas holes 144, thereby improving the ionization efficiency of the process gas. And since the second baffle plate 172 and the third baffle plate 173 are both inclined toward the right side wall 142, the part of the second electrode 162 exposed within the ionization chamber 140 on the left side of the second baffle plate 172 and the third baffle plate 173 is more than the part located within the vacuum chamber 145, thereby increasing the ionization area of the second electrode 162 within the ionization chamber 140. In addition, since the second electrode 162 is partially located in the ionization chamber 140 and the other part is located in the vacuum chamber 145, the second electrode 162 will generate an electric field only in the ionization chamber 140 on the left side of the second baffle plate 172 and the third baffle plate 173, and will not generate an electric field in the vacuum chamber 145, so that the electric field generated by the second electrode 162 is entirely used for ionization of the process gas and is not absorbed by the inner wall of the ionization chamber 140, thereby playing a role in saving power. In addition, as shown in FIG. 2(e), the inner tube 110 may be fixed to the left side wall 141 and the right side wall 142 of the ionization chamber 140 on the basis of the sixth embodiment, and the additional gas supply tubes 180 may be located near the ionization chamber 140 and are provided close to the inner wall of the inner tube 110. The radius of the inner tube 110 at the position of the additional gas supply tubes 180 is larger than the radius of the inner tube 110 at other positions, and the additional gas supply tubes 180 are located within the inner tube 110 and approximately on the same arc line as the first gas holes 144, so that the distance between the additional gas supply tubes 180 and the plurality of substrates is approximately equal to the distance between the first gas holes 144 and the plurality of substrates.

### Embodiment 9

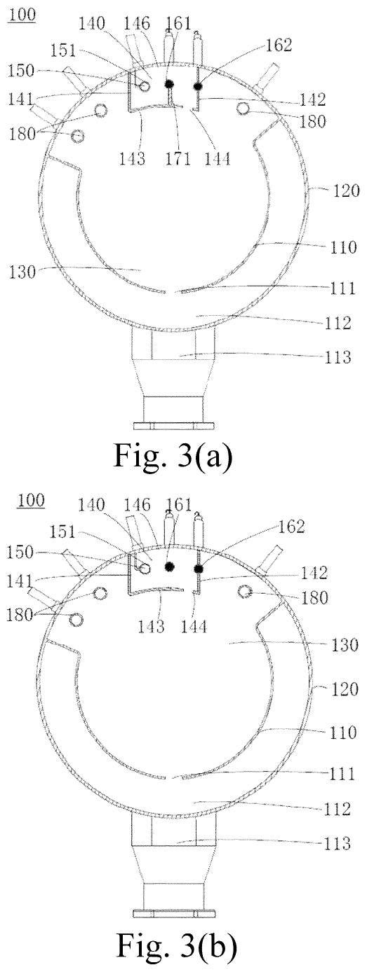

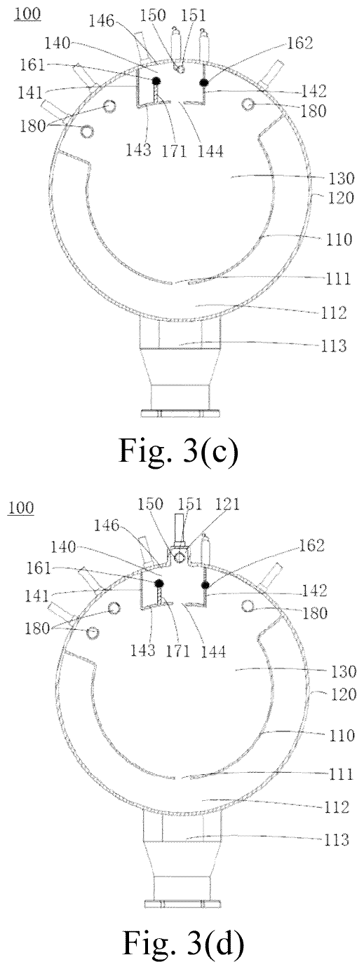

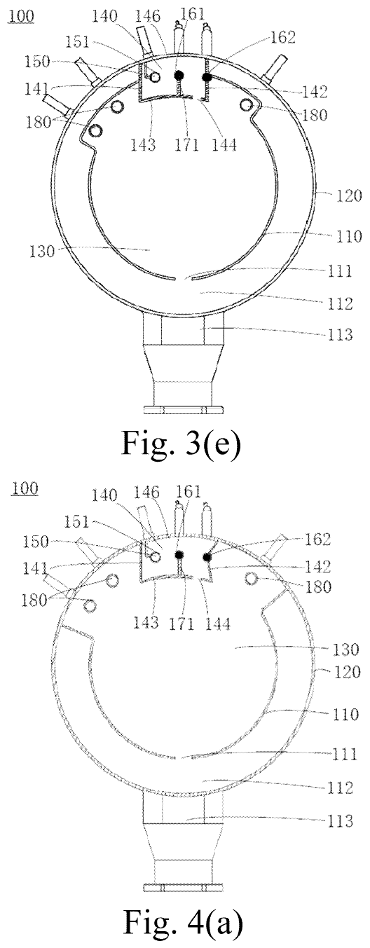

As shown in FIG. 3(a), in the ninth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

This embodiment differs from the fifth embodiment only in the position of the second electrode 162 and the number of baffle plates. In the fifth embodiment, the second electrode 162 and the second inner side wall 143 are connected to a second baffle plate 172, a third baffle 173 is connected between the second electrode 162 and the first inner side wall 146, and the right side of the second baffle plate 172 and the third baffle plate 173 and the right side wall 142 of the ionization chamber 140 form a vacuum chamber 145. In the present embodiment, the second electrode 162 is disposed on the right side wall 142, and the second baffle plate 172 and the third baffle plate 173 are eliminated. The second electrode 162 is located partially within the ionization chamber 140 and partially outside the ionization chamber 140. In the present embodiment, the second electrode 162 is located partially within the ionization chamber 140 and partially within the reaction chamber 130.

In the present embodiment, the first baffle plate 171 blocks the flow of the process gas to be ionized along the space between the second inner side wall 143 and the first electrode 161, so that the process gas to be ionized must pass through the ionization area between the first electrode 161 and the second electrode 162 and the flow channel between the first baffle plate 171 and the right side wall 142 of the ionization chamber 140 before entering the reaction chamber 130 through the first gas holes 144, thereby improving the ionization efficiency of the process gas. Besides, since the second electrode 162 is located locally outside the ionization chamber 140, the second electrode 162 will generate an electric field only in the ionization chamber 140, and will not generate an electric field outside the ionization chamber 140, so that the electric field generated by the second electrode 162 is entirely used for ionization of the process gas and is not absorbed by the inner wall of the ionization chamber 140, thereby playing a role of saving power.

Besides, as shown in FIG. 3(b), the first baffle plate 171 may be eliminated on the basis of the ninth embodiment.

As shown in FIG. 3(c), only the gas supply tube 150 can be adjusted to the vertical line of the line connecting between the first electrode 161 and the second electrode 162 on the basis of the ninth embodiment.

As shown in FIG. 3(d), the gas supply tube 150 may be adjusted on the vertical line of the line connecting between the first electrode 161 and the second electrode 162 on the basis of the ninth embodiment, and may be disposed outside the radius range of the process tube 120. The process tube 120 may be configured along the axial direction thereof with the convex groove structure 121 for installing the gas supply tube 150, thereby increasing the distance between the gas supply tube 150 and the first gas holes 144, increasing the time for the process gas to pass through the first electrode 161 and the second electrode 162, and enabling the process gas to have sufficient ionization time.

As shown in FIG. 3(e), the inner tube 110 can be fixed to the left side wall 141 and the right side wall 142 of the ionization chamber 140 on the basis of the ninth embodiment, and the additional gas supply tubes 180 are located near the ionization chamber 140 and are provided close to the inner wall of the inner tube 110. The radius of the inner tube 110 at the position of the additional gas supply tubes 180 is larger than the radius of the inner tube 110 at other positions, and the additional gas supply tubes 180 are located within the inner tube 110 and approximately on the same arc line as the first gas holes 144, so that the distance between the additional gas supply tubes 180 and the plurality of substrates is approximately equal to the distance between the first gas holes 144 and the plurality of substrates.

### Embodiment 10

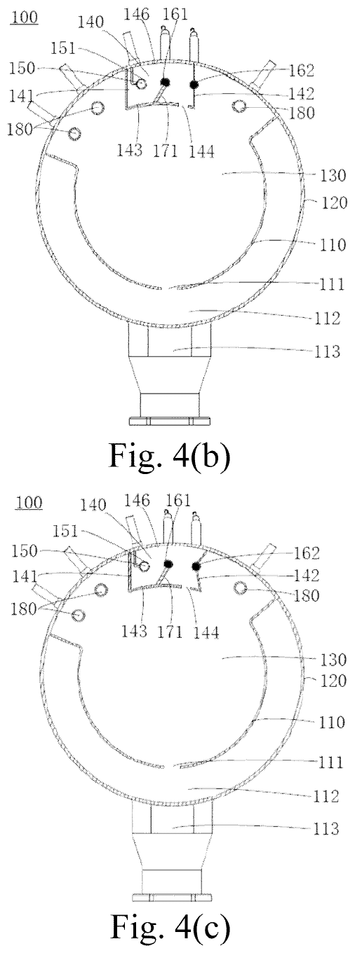

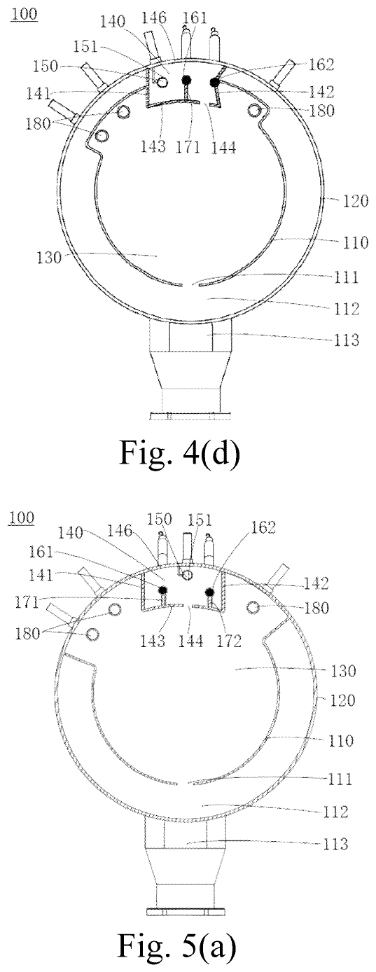

As shown in FIG. 4(a), in the tenth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The present embodiment differs from the ninth embodiment only in the structure of the right side wall 142. In the ninth embodiment, the right side wall 142 is parallel to the left side wall 141. In the present embodiment, the connection position of the right side wall 142 and the first inner side wall 146 is offset to the side away from the left side wall 141, and the connection position of the right side wall 142 and the second inner side wall 143 is offset to the side away from the left side wall 141, such that the upper end of the right side wall 142 forms an acute angle with the first inner side wall 146, and the lower end of the right side wall 142 forms an acute angle with the second inner side wall 143.

In the present embodiment, the first baffle plate 171 blocks the flow of the process gas to be ionized along the space between the second inner side wall 143 and the first electrode 161, so that the process gas to be ionized must pass through the ionization area between the first electrode 161 and the second electrode 162 and the flow channel between the first baffle plate 171 and the right side wall 142 before entering the reaction chamber 130 through the first gas holes 144, thereby improving the ionization efficiency of the process gas. Since both ends of the right side wall 142 are inclined toward the side away from the left side wall 141, the part of the second electrode 162 exposed in the ionization chamber 140 on the left side of the right side wall 142 is more than the part located outside the ionization chamber 140, thereby increasing the ionization area of the second electrode 162 in the ionization chamber 140. Besides, since the second electrode 162 is located locally outside the ionization chamber 140, the second electrode 162 will generate an electric field only in the ionization chamber 140 on the left side of the right side wall 142, and will not generate an electric field outside the ionization chamber 140, so that the electric field generated by the second electrode 162 is entirely used for ionization of the process gas and is not absorbed by the inner wall of the ionization chamber 140, thereby playing a role in saving power.

### Embodiment 11

As shown in FIG. 4(b), in the eleventh embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between this embodiment and the ninth embodiment is only in the placement position of the first baffle plate 171. In the ninth embodiment, the first baffle plate 171 is perpendicular to the second inner side wall 143. In the present embodiment, the connection position of the first baffle plate 171 and the second inner side wall 143 is offset to the side close to the left side wall 141, so that the first baffle plate 171 forms the acute angle with the second inner wall 143.

In the present embodiment, the first baffle plate 171 blocks the flow of the process gas to be ionized along the space between the second inner side wall 143 and the first electrode 161, and since the first baffle plate 171 is inclined, so that the process gas to be ionized provided by the gas supply tube 150 tends to flow between the first electrode 161 and the first inner side wall 146. Hence, the process gas to be ionized must pass through the ionization area between the first electrode 161 and the second electrode 162 and the flow channel between the first baffle plate 171 and the right side wall 142 of the ionization chamber 140 before entering the reaction chamber 130 through the first gas holes 144. And since the first baffle plate 171 is inclined, the ionization area between the right side of the first electrode 161 and the second electrode 162 is increased, thereby improving the ionization efficiency of the process gas. In addition, since the second electrode 162 is located locally outside the ionization chamber 140, the second electrode 162 will generate an electric field only inside the ionization chamber 140, and will not generate an electric field outside the ionization chamber 140, so that the electric field generated by the second electrode 162 is entirely used for ionization of the process gas and is not absorbed by the inner wall of the ionization chamber 140, thereby playing a role of saving power.

### Embodiment 12

As shown in FIG. 4(c), in the twelfth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The difference between this embodiment and the tenth embodiment is only in the placement position of the first baffle plate 171. In the tenth embodiment, the first baffle plate 171 is perpendicular to the second inner side wall 143. In the present embodiment, the connection position between the first baffle plate 171 and the second inner side wall 143 is offset to the side close to the left side wall 141, such that the first baffle plate 171 forms the acute angle with the second inner side wall 143.

In the present embodiment, the first baffle plate 171 blocks the flow of the process gas to be ionized along the space between the second inner side wall 143 and the first electrode 161. And since the first baffle plate 171 is inclined, the process gas to be ionized supplied by the gas supply tube 150 tends to flow between the first electrode 161 and the first inner side wall 146, so that the process gas to be ionized must pass through the ionization area between the first electrode 161 and the second electrode 162 and the flow channel between the first baffle plate 171 and the right side wall 142 of the ionization chamber 140 before entering the reaction chamber 130 through the first gas holes 144, thereby improving the ionization efficiency of the process gas. And since both ends of the right side wall 142 are inclined toward the side away from the left side wall 141, the part of the second electrode 162 exposed in the ionization chamber 140 on the left side of the right side wall 142 is more than the part located outside the ionization chamber 140, thereby increasing the ionization area of the second electrode 162 in the ionization chamber 140. Besides, since the second electrode 162 is located locally outside the ionization chamber 140, the second electrode 162 generates an electric field only in the ionization chamber 140 on the left side of the right side wall 142, and does not generate an electric field outside the ionization chamber 140, so that the electric field generated by the second electrode 162 is entirely used for ionization of the process gas and is not absorbed by the inner wall of the ionization chamber 140, thereby playing a role in saving power.

As shown in FIG. 4(d), the inner tube 110 may be fixed to the left side wall 141 and the right side wall 142 of the ionization chamber 140 on the basis of the tenth embodiment, and the additional gas supply tubes 180 are located near the ionization chamber 140 and are provided close to the inner wall of the inner tube 110. The radius of the inner tube 110 at the position of the additional gas supply tubes 180 is larger than the radius of the inner tube 110 at other positions, and the additional gas supply tubes 180 are located within the inner tube 110 and approximately on the same arc line as the first gas holes 144, so that the distance between the additional gas supply tubes 180 and the plurality of substrates is approximately equal to the distance between the first gas holes 144 and the plurality of substrates.

### Embodiment 13

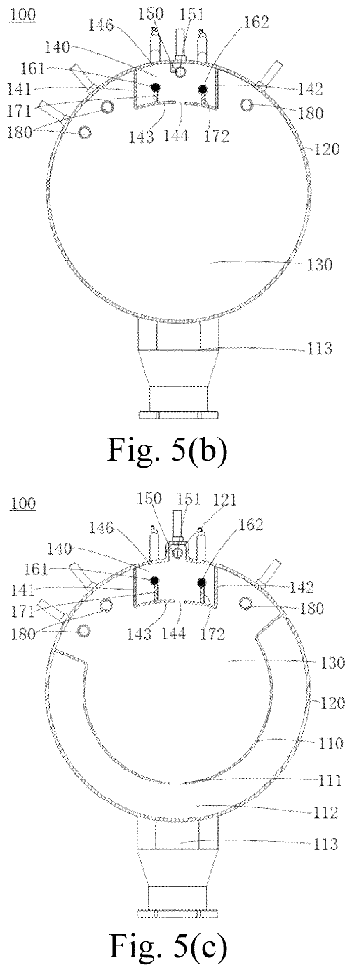

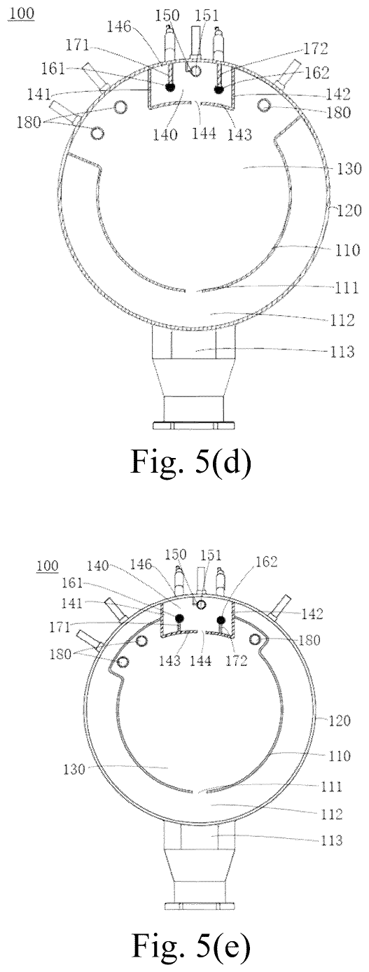

As shown in FIG. 5(a), in the thirteenth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The present embodiment differs from the first embodiment only in the relative positions of the gas supply tube 150, the first electrode 161 and the second electrode 162. In the first embodiment, the gas supply tube 150 is disposed close to the left side wall 141, the first electrode 161 is disposed at the middle position between the left side wall 141 and the right side wall 142, and the second electrode 162 is disposed close to the right side wall 142. In the present embodiment, the gas supply tube 150 is disposed close to the first inner side wall 146, and the first electrode 161 is disposed close to the left side wall 141. The second electrode 162 is disposed close to the right side wall 142, and the gas supply tube 150 and the first gas holes 144 are disposed on the vertical line of the line connecting between the first electrode 161 and the second electrode 162.

In the present embodiment, the first baffle plate 171 blocks the flow of the process gas to be ionized along the space between the second inner side wall 143 on the left side of the first gas holes 144 and the first electrode 161, and the second baffle plate 172 blocks the flow of the process gas to be ionized along the space between the second inner side wall 143 on the right side of the first gas holes 144 and the second electrode 162, so that the process gas to be ionized must pass through the ionization area between the first electrode 161 and the second electrode 162 and the flow channel between the first baffle plate 171 and the second baffle plate 172 before entering the reaction chamber 130 through the first gas holes 144, thereby improving the ionization efficiency of the process gas.

Besides, as shown in FIG. 5(b), the inner tube 110 may be eliminated on the basis of the thirteenth embodiment, and a single-tube furnace tube may be adopted.

As shown in FIG. 5(c), the gas supply tube 150 may be disposed outside the radius range of the process tube 120 on the basis of the thirteenth embodiment, and the convex groove structure 121 for installing the gas supply tube 150 may be adaptively disposed on the process tube 120 along the axial direction thereof, thereby increasing the distance between the gas supply tube 150 and the first gas holes 144, and increasing the degree of ionization of the process gas.

As shown in FIG. 5(d), the first baffle plate 171 may be adjusted between the first electrode 161 and the first inner side wall 146 on the left side of the gas supply tube 150 on the basis of the thirteenth embodiment, and the second baffle plate 172 may be adjusted between the second electrode 162 and the first inner side wall 146 on the right side of the gas supply tube 150.

As shown in FIG. 5(e), the inner tube 110 can be fixed to the left side wall 141 and the right side wall 142 of the ionization chamber 140 on the basis of the thirteenth embodiment, and the additional gas supply tubes 180 are located near the ionization chamber 140 and are provided close to the inner wall of the inner tube 110. The radius of the inner tube 110 at the position of the additional gas supply tubes 180 is larger than the radius of the inner tube 110 at other positions. The additional gas supply tubes 180 are located within the inner tube 110 and approximately on the same arc line as the first gas holes 144, such that the distance from the additional gas supply tubes 180 to the plurality of substrates is approximately equal to the distance from the first gas holes 144 to the plurality of substrates.

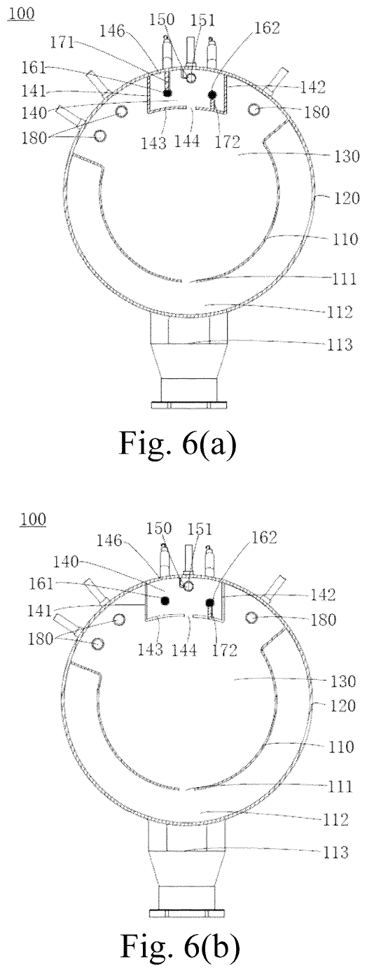

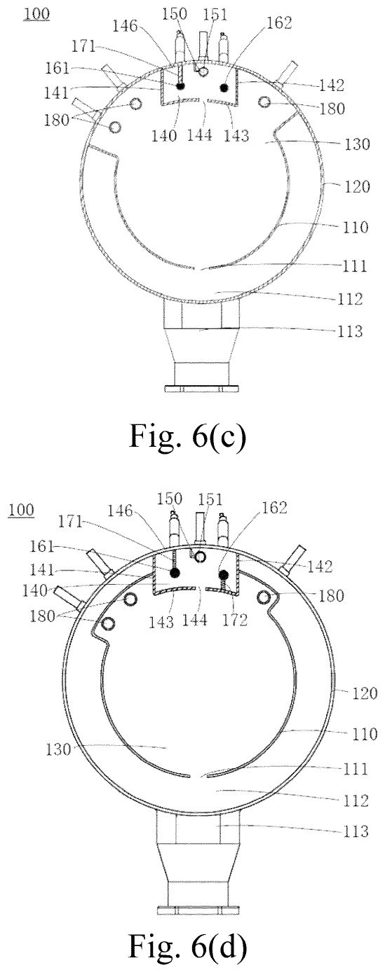

As shown in FIG. 6(a), the first baffle plate 171 may be adjusted between the first electrode 161 and the first inner side wall 146 on the left side of the gas supply tube 150 on the basis of the thirteenth embodiment.

As shown in FIG. 6(b), the first baffle plate 171 may be eliminated on the basis of the thirteenth embodiment.

As shown in FIG. 6(c), the second baffle plate 172 may be eliminated on the basis of the thirteenth embodiment, and the first baffle plate 171 may be adjusted between the first electrode 161 and the first inner side wall 146 on the left side of the gas supply tube 150.

As shown in FIG. 6(d), the first baffle plate 171 may be adjusted between the first electrode 161 and the first inner side wall 146 on the left side of the gas supply tube 150 on the basis of the thirteenth embodiment, and the inner tube 110 may be fixed to the left side wall 141 and the right side wall 142 of the ionization chamber 140. The additional gas supply tubes 180 are located near the ionization chamber 140 and are provided close to the inner wall of the inner tube 110. The radius of the inner tube 110 at the position of the additional gas supply tubes 180 is larger than the radius of the inner tube 110 at other positions, and the additional gas supply tubes 180 are located within the inner tube 110 and approximately on the same arc line as the first gas holes 144.

### Embodiment 14

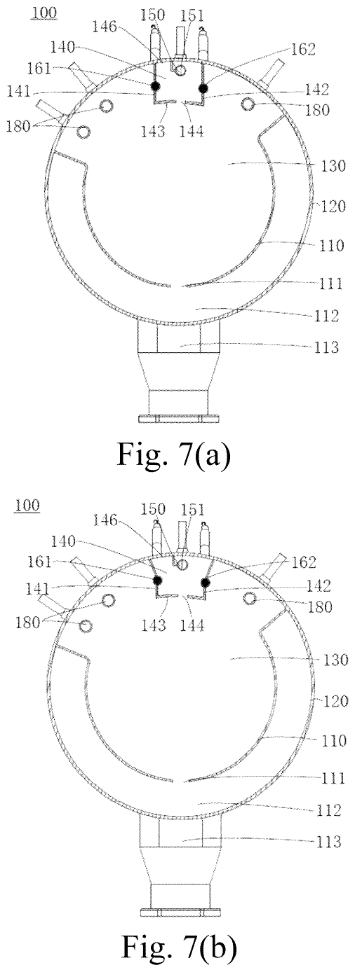

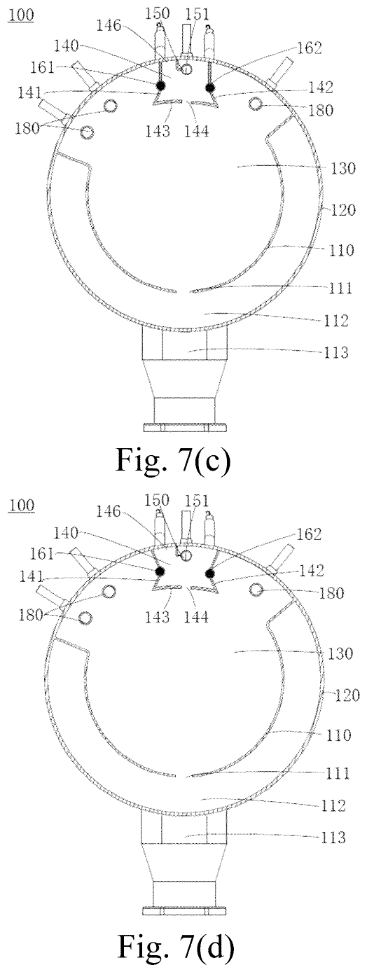

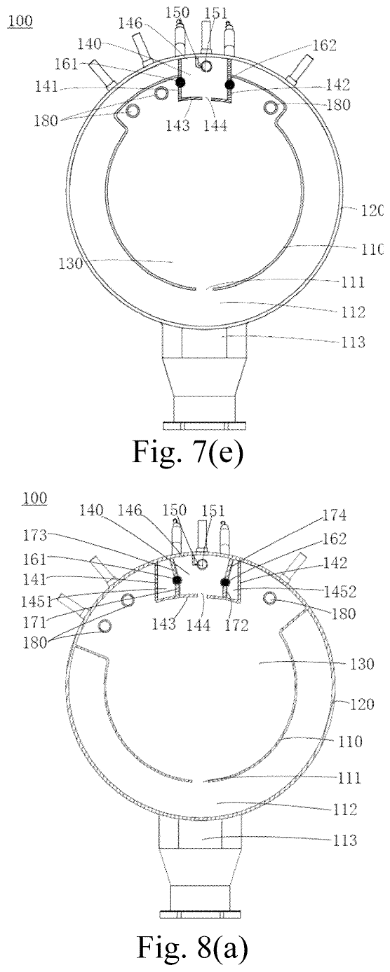

As shown in FIG. 7(a), in the fourteenth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The present embodiment differs from the thirteenth embodiment only in the arrangements positions of the first electrode 161 and the second electrode 162. In the thirteenth embodiment, the first electrode 161 is provided close to the left side wall 141, and the second electrode 162 is provided close to the right side wall 142. The gas supply tube 150 and the first gas holes 144 are located on the vertical line of the line connecting between the first electrode 161 and the second electrode 162. The first baffle plate 171 is provided between the second inner side wall 143 on the left side of the first gas holes 144 and the first electrode 161, and the second baffle plate 172 is provided between the second inner side wall 143 on the right side of the first gas holes 144 and the second electrode 162. In this embodiment, the first baffle plate 171 and the second baffle plate 172 are eliminated, the first electrode 161 is disposed on the left side wall 141, and the second electrode 162 is disposed on the right side wall 142. And the face-to-face side of the first electrode 161 and the second electrode 162 is located inside the ionization chamber 140, and the opposite side of the first electrode 161 and the second electrode 162 is located outside the ionization chamber 140.

In the present embodiment, both the gas supply tube 150 and the first gas holes 144 are located on the vertical line of the line connecting between the first electrode 161 and the second electrode 162, and both the gas supply tube 150 and the first gas holes 144 are located between the left side wall 141 and the right side wall 142, so that the process gas to be ionized must pass through the ionization area between the first electrode 161 and the second electrode 162 and the flow channel between the left side wall 141 and the right side wall 142 before entering the reaction chamber 130 through the first gas holes 144, thereby improving the ionization efficiency of the process gas. Besides, since the first electrode 161 and the second electrode 162 are located locally outside the ionization chamber 140, the first electrode 161 and the second electrode 162 generate an electric field only inside the ionization chamber 140, and do not generate an electric field outside the ionization chamber 140, so that the electric field generated by the first electrode 161 and the second electrode 162 is used entirely for ionization of the process gas and is not absorbed by the inner wall of the ionization chamber 140, thereby playing a role of saving power.

### Embodiment 15

As shown in FIG. 7(b), in the fifteenth embodiment of the present invention, this embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

The present embodiment differs from the fourteenth embodiment only in the structures of the left side wall 141 and the right side wall 142. In the fourteenth embodiment, the left side wall 141 and the right side wall 142 are parallel. In the present embodiment, the left side wall 141 located between the first electrode 161 and the second inner side wall 143 is parallel to the right side wall 142 located between the second electrode 162 and the second inner side wall 143, and the left side wall 141 located between the first electrode 161 and the first inner side wall 146 and the right side wall 142 located between the second electrode 162 and the first inner side wall 146 are inclined in opposite directions. In other words, the distance between the parts of the left side wall 141 and the right side wall 142 located between the electrodes and the first inner side wall 146 gradually increases, and the parts located between the electrodes and the second inner side wall 143 are parallel to each other.

In the present embodiment, both the gas supply tube 150 and the first gas holes 144 are located on the vertical line of the line connecting between the first electrode 161 and the second electrode 162, and both the gas supply tube 150 and the first gas holes 144 are located between the left side wall 141 and the right side wall 142, so that the process gas to be ionized must pass through the ionization area between the first electrode 161 and the second electrode 162 and the flow channel between the left side wall 141 and the right side wall 142 before entering the reaction chamber 130 through the first gas holes 144, thereby improving the ionization efficiency of the process gas. And since the left side wall 141 and the right side wall 142 are inclined in opposite directions along the same end, the part of the first electrode 161 and the second electrode 162 exposed within the ionization chamber 140 is more than the part outside the ionization chamber 140, thereby increasing the ionization area of the first electrode 161 and the second electrode 162 in the ionization chamber 140. In addition, since the first electrode 161 and the second electrode 162 are located locally outside the ionization chamber 140, the first electrode 161 and the second electrode 162 will generate an electric field only inside the ionization chamber 140, and will not generate an electric field outside the ionization chamber 140, so that the electric field generated by the first electrode 161 and the second electrode 162 is entirely used for ionization of the process gas and is not absorbed by the inner wall of the ionization chamber 140, thereby playing a role of saving power.

Besides, as shown in FIG. 7(c), only the structures of the left side wall 141 and the right side wall 142 may be changed on the basis of the fifteenth embodiment. The left side wall 141 between the first electrode 161 and the second inner side wall 143 and the right side wall 142 between the second electrode 162 and the second inner side wall 143 are inclined in opposite directions, and the left side wall 141 between the first electrode 161 and the first inner side wall 146 is parallel to the right side wall 142 between the second electrode 162 and the first inner side wall 146.

As shown in FIG. 7(d), only the structures of the left side wall 141 and the right side wall 142 may be changed on the basis of the fifteenth embodiment. The left side wall 141 located between the first electrode 161 and the second inner side wall 143 and the right side wall 142 located between the second electrode 162 and the second inner side wall 143 may be inclined in opposite directions, and the left side wall 141 located between the first electrode 161 and the first inner side wall 146 and the right side wall 142 located between the second electrode 162 and the first inner side wall 146 may be inclined in opposite directions, such that the distance between the first electrode 161 and the second electrode 162 is smaller than the distance between any two points of the left side wall 141 and the right side wall 142.

As shown in FIG. 7(e), the inner tube 110 can be fixed to the left side wall 141 and the right side wall 142 of the ionization chamber 140 on the basis of the fourteenth embodiment, and the additional gas supply tubes 180 are located near the ionization chamber 140 and are provided close to the inner wall of the inner tube 110. The radius of the inner tube 110 at the position of the additional gas supply tubes 180 is larger than the radius of the inner tube 110 at other positions, and the additional gas supply tubes 180 are located within the inner tube 110 and approximately on the same arc line as the first gas holes 144, so that the distance between the additional gas supply tubes 180 and the plurality of substrates is approximately equal to the distance between the first gas holes 144 and the plurality of substrates.

### Embodiment 16

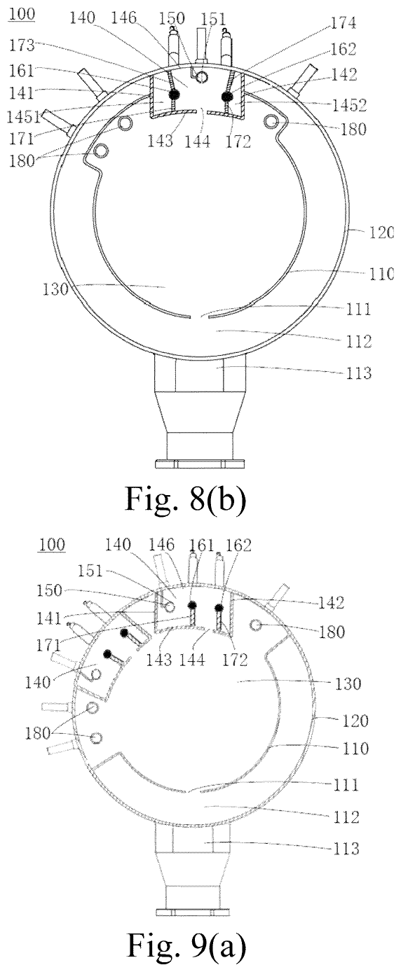

As shown in FIG. 8(a), in the sixteenth embodiment of the present invention, the present embodiment further defines the internal structure of the ionization chamber 140 and the arrangement positions of the first electrode 161, the second electrode 162 and the gas supply tube 150 in the ionization chamber 140 on the basis of the overall structure of the furnace tube 100.

This embodiment differs from the thirteenth embodiment only in the number of baffle plates. In the thirteenth embodiment, the baffle plate comprises a first baffle plate 171 disposed between the first electrode 161 and the second inner side wall 143 on the left side of the first gas holes 144, and a second baffle plate 172 disposed between the second electrode 162 and the second inner side wall 143 on the right side of the first gas holes 144. In the present embodiment, a third baffle plate 173 and a fourth baffle plate 174 are added, the third baffle plate 173 is provided between the first electrode 161 and the first inner side wall 146 on the left side of the gas supply tube 150, and the fourth baffle plate 174 is provided between the second electrode 162 and the first inner side wall 146 on the right side of the gas supply tube 150. A left vacuum chamber 1451 is formed between the left side of the first baffle plate 171 and the third baffle plate 173 and the left side wall 141, a right vacuum chamber 1452 is formed between the right side of the second baffle plate 172 and the fourth baffle plate 174 and the right side wall 142, and the vacuum degree in the left vacuum chamber 1451 and the right vacuum chamber 1452 can be controlled independently and respectively. The left side of the first electrode 161 is located in the left vacuum chamber 1451, and the right side of the first electrode 161 is located in the ionization area; The right side of the second electrode 162 is located in the right vacuum chamber 1452, and the left side of the second electrode 162 is located in the ionization area.

In the present embodiment, the lifting mechanism lifts the wafer boat carrying the plurality of substrates into the reaction chamber 130, and the process gas to be ionized enters the ionization chamber 140 through the gas supply tube 150 and the second gas holes 151. In the ionization chamber 140, the process gas to be ionized will flow along the space between the third baffle plate 173 and the fourth baffle plate 174 and between the first baffle plate 171 and the second baffle plate 172, so that the process gas to be ionized must pass through the ionization area between the first electrode 161 and the second electrode 162 before entering the reaction chamber 130 through the first gas holes 144, thereby improving the ionization efficiency of the process gas. Besides, since the first electrode 161 is located locally in the left vacuum chamber 1451 and the second electrode 162 is located locally in the right vacuum chamber 1452, the first electrode 161 and the second electrode 162 generate an electric field only in the ionization chamber 140 on the face-to-face side thereof, and do not generate an electric field in the left vacuum chamber 1451 and the right vacuum chamber 1452, so that the electric field generated by the first electrode 161 and the second electrode 162 is entirely used for ionization of the process gas and is not absorbed by the inner wall of the ionization chamber 140, thereby playing a role in saving power. The ionized process gas enters the reaction chamber 130 through the respective first gas holes 144 and is uniformly supplied to the respective substrates carried by the wafer boat. When the gas in the reaction chamber 130 is replaced or discharged, the original gas in the reaction chamber 130 is firstly pumped from the third gas holes 111 to the suction chamber 112, and then is pumped out of the process tube 120 by the exhaust tubes 113. Besides, as shown in FIG. 8(b), the inner tube 110 may be fixed to the left side wall 141 and the right side wall 142 of the ionization chamber 140 on the basis of the sixteenth embodiment, and the additional gas supply tubes 180 are located near the ionization chamber 140 and are provided close to the inner wall of the inner tube 110. The radius of the inner tube 110 at the position of the additional gas supply tubes 180 is larger than the radius of the inner tube 110 at other positions, and the additional gas supply tubes 180 are located within the inner tube 110 and approximately on the same arc line as the first gas holes 144, so that the distance between the additional gas supply tubes 180 and the plurality of substrates is approximately equal to the distance between the first gas holes 144 and the plurality of substrates.

It should be noted that all of the above-described embodiments can be freely combined as necessary. The above are only preferred embodiments of the present invention, and those of ordinary skill in the art can make some improvements and retouches without departing from the principles of the present invention, and these improvements and retouches should also be regarded as the scope of protection of the present invention.

What is claimed is:

1. A furnace tube for plasma enhanced thin film deposition, comprising:
a process tube, including a reaction chamber capable of accommodating a plurality of substrates and at least one ionization chamber disposed along the stacking direction of the plurality of substrates, the ionization chamber being provided with a plurality of first gas holes communicating with the reaction chamber;
a gas supply tube, located in the ionization chamber, and provided with a plurality of second gas holes sequentially along the stacking direction of the plurality of substrates, the gas supply tube being used for transporting the process gas to be ionized and the process gas to be ionized being introduced into the ionization chamber through the second gas holes, after the process gas to be ionized being ionized in the ionization chamber, the ionized process gas being introduced into the reaction chamber through the first gas holes, so as to deposit a corresponding thin film on the surface of the substrate;
a first electrode and a second electrode, located in the process tube and at the middle position of the ionization chamber, and arranged along the stacking direction of the plurality of substrates;
wherein, the first electrode and/or the second electrode are/is supported by a baffle plate, one end of each baffle plate is connected to the corresponding electrode, and the other end of each baffle plate is connected to the inner wall of the ionization chamber, so that the process gas to be ionized passes between the first electrode and the second electrode to improve the ionization efficiency of the process gas, and the first gas holes are located on the vertical line of the line connecting between the first electrode and the second electrode.

2. The furnace tube for plasma enhanced thin film deposition according to claim 1, the process tube further comprising:
an inner tube, being configured within the process tube, the inner tube forming a concentric circular structure with the process tube, the plurality of substrates being positioned in the inner tube;
the radial distance between the first gas holes and the inner wall of the process tube being not less than the radial distance between the inner tube and the inner wall of the process tube.

3. The furnace tube for plasma enhanced thin film deposition according to claim 1, wherein,
the side wall of the process tube is configured with an exhaust tube corresponding to the ionization chamber.

4. The furnace tube for plasma enhanced thin film deposition according to claim 1, wherein,
the gas supply tube is located on the same side of the first electrode and the second electrode.

5. The furnace tube for plasma enhanced thin film deposition according to claim 1, wherein,
the gas supply tube is located on the vertical line of the line connecting between the first electrode and the second electrode.

6. The furnace tube for plasma enhanced thin film deposition according to claim 4, wherein,
a part of the inner wall of the process tube constitutes a first inner side wall of the ionization chamber, the ionization chamber further comprises a left side wall, a right side wall and a second inner side wall opposite to the first inner side wall, the same ends of the left side wall and the right side wall of the ionization chamber are connected to the first inner side wall respectively, and the other ends of the left side wall and the right side wall are connected to the second inner side wall respectively, so as to form the hollow ionization chamber along the axial direction of the process tube;
the first electrode and the second electrode are sequentially located on the same arc line, and the arc line is located at the middle position of the first inner side wall and the second inner side wall.

7. The furnace tube for plasma enhanced thin film deposition according to claim 5, wherein,
a part of the inner wall of the process tube constitutes a first inner side wall of the ionization chamber, the ionization chamber further comprises a left side wall, a right side wall and a second inner side wall opposite to the first inner side wall, the same ends of the left side wall and the right side wall of the ionization chamber are connected to the first inner side wall respectively, and the other ends of the left side wall and the right side wall of the ionization chamber are connected to the second inner side wall respectively, so as to form the hollow ionization chamber along the axial direction of the process tube;
the first electrode and the second electrode are sequentially located on the same arc line, the arc line is located at the middle position of the first inner side wall and the second inner side wall, the gas supply tube is close to the side of the inner wall of the process tube, and the gas supply tube and the first gas holes are both located on the vertical line of the line connecting between the first electrode and the second electrode.

8. The furnace tube for plasma enhanced thin film deposition according to claim 7, wherein,
the gas supply tube is located outside the radius of the process tube, and the process tube is configured along the axial direction with a convex groove structure for accommodating the gas supply tube.

9. The furnace tube for plasma enhanced thin film deposition according to claim 6, wherein,
a first baffle plate is connected between the first electrode and the second inner side wall;
a second baffle plate is connected between the second electrode and the second inner side wall, or the right side wall, or the first inner side wall;
the first gas holes are located between the first baffle plate and the second baffle plate.

10. The furnace tube for plasma enhanced thin film deposition according to claim 9, wherein,
the first baffle plate and the second baffle plate are parallel and perpendicular to the second inner side wall;
or the first baffle plate is perpendicular to the second inner side wall, the second baffle plate forms an acute angle with the right side wall;
or the first baffle plate forms an acute angle with the second inner side wall, and the second baffle plate forms the acute angle with the right side wall.

11. The furnace tube for plasma enhanced thin film deposition according to claim 6, wherein,
a first baffle plate is connected between the first electrode and the second inner side wall;
a second baffle plate is connected between the second electrode and the second inner side wall, a third baffle plate is connected between the second electrode and the right side wall or the first inner side wall, a vacuum chamber is provided between the second baffle plate and the third baffle plate and the right side wall, a part of the second electrode is located on the side of the second baffle plate and the third baffle plate close to the first electrode, and the other part of the second electrode is located in the vacuum chamber;
the first gas holes are located between the first baffle plate and the second baffle plate.

12. The furnace tube for plasma enhanced thin film deposition according to claim 11, wherein,
the vacuum degree in the vacuum chamber is independently controlled.

13. The furnace tube for plasma enhanced thin film deposition according to claim 11, wherein,
the first baffle plate and the second baffle plate are parallel and perpendicular to the second inner side wall, the third baffle plate and the second baffle plate are located on the same straight line;
or the first baffle plate is perpendicular to the second inner side wall, the second baffle plate and the third baffle plate form acute angles with the right side wall respectively;
or the first baffle plate forms the acute angle with the second inner side wall, the second baffle plate is perpendicular to the second inner side wall, and the third baffle plate and the second baffle plate are located on the same straight line;
or the first baffle plate forms the acute angle with the second inner side wall, the second baffle plate and the third baffle plate form acute angles with the right side wall respectively.

14. The furnace tube for plasma enhanced thin film deposition according to claim 7, wherein,
a first baffle plate is connected between the first electrode and the second inner side wall or the first inner side wall;
a second baffle plate is connected between the second electrode and the second inner side wall or the first inner side wall;
the first gas holes are located between the first baffle plate and the second baffle plate.

15. The furnace tube for plasma enhanced thin film deposition according to claim 7, wherein,
a first baffle plate is connected between the first electrode and the second inner side wall, a fourth baffle plate is connected between the first electrode and the first inner side wall, a left vacuum chamber is provided between the first baffle plate and the fourth baffle plate and the left side wall, a part of the first electrode is located on the side of the first baffle plate and the fourth baffle plate close to the second electrode, and the other part of the first electrode is located in the left vacuum chamber;
a second baffle plate is connected between the second electrode and the second inner side wall, the third baffle plate is connected between the second electrode and the first inner side wall, a right vacuum chamber is provided between the second baffle plate and the third baffle plate and the right side wall, a part of the second electrode is located on the side of the second baffle plate and the third baffle plate close to the first electrode, and the other part of the second electrode is located in the right vacuum chamber;
the first gas holes are located between the first baffle plate and the second baffle plate, and the gas supply tube is located between the fourth baffle plate and the third baffle plate.

16. The furnace tube for plasma enhanced thin film deposition according to claim 15, wherein,
the vacuum degrees in the left vacuum chamber and in the right vacuum chamber are independently controlled.

17. The furnace tube for plasma enhanced thin film deposition according to claim 1, wherein,
the flow area ratio of the gas supply tube to the second gas holes is in the range of 1: (0.21-0.48).

18. A furnace tube for plasma enhanced thin film deposition, comprising:
a process tube, including a reaction chamber capable of accommodating a plurality of substrates and at least one ionization chamber disposed along the stacking direction of the plurality of substrates, the ionization chamber being provided with a plurality of first gas holes communicating with the reaction chamber;
a gas supply tube, located in the ionization chamber, and provided with a plurality of second gas holes sequentially along the stacking direction of the plurality of substrates, the gas supply tube being used for transporting the process gas to be ionized and the process gas to be ionized being introduced into the ionization chamber through the second gas holes, after the process gas to be ionized being ionized in the ionization chamber, the ionized process gas being introduced into the reaction chamber through the first gas holes, so as to deposit a corresponding thin film on the surface of the substrate;
a first electrode and a second electrode, located in the process tube, and arranged along the stacking direction of the plurality of substrates, the first electrode and/or the second electrode being located on the side wall of the ionization chamber, and a part of the electrode located on the side wall of the ionization chamber being located inside the ionization chamber, and the other part being located outside the ionization chamber.

19. The furnace tube for plasma enhanced thin film deposition according to claim 18, the process tube further comprising:
an inner tube, being configured within the process tube, the inner tube forming a concentric circular structure with the process tube, the plurality of substrates being located in the inner tube;
the radial distance between the first gas holes and the inner wall of the process tube is not less than the radial distance between the inner tube and the inner wall of the process tube.

20. The furnace tube for plasma enhanced thin film deposition according to claim 19, wherein, the side wall of the process tube is configured with the exhaust tube corresponding to the ionization chamber.

21. The furnace tube for plasma enhanced thin film deposition according to claim 18, wherein,
the first electrode is located at the middle position of the ionization chamber, the second electrode is located on the side wall of the ionization chamber, and the second electrode is configured to be partially located within the ionization chamber and the other part is located outside the ionization chamber;
the first electrode is supported by a baffle plate, one end of the baffle plate is connected to the first electrode, and the other end of the baffle plate is connected to the inner wall of the ionization chamber, so that the process gas to be ionized passes between the first electrode and the second electrode to improve the ionization efficiency of the process gas, and the first gas holes are located on the vertical line of the line connecting between the first electrode and the second electrode.

22. The furnace tube for plasma enhanced thin film deposition according to claim 18, wherein,
the first electrode is located on the left side wall of the ionization chamber, the second electrode is located on the right side wall of the ionization chamber, and the first electrode and the second electrode are respectively configured such that the part of the electrode is located within the ionization chamber and the other part is located outside the ionization chamber;
both the gas supply tube and the first gas holes are located on the vertical line of the line connecting between the first electrode and the second electrode, and the gas supply tube is close to the inner wall of the process tube, so that the process gas provided by the gas supply tube passes between the first electrode and the second electrode, thereby improving the ionization efficiency of the process gas.

23. The furnace tube for plasma enhanced thin film deposition according to claim 21, wherein,
the gas supply tube is located on the side of the first electrode away from the second electrode.

24. The furnace tube for plasma enhanced thin film deposition according to claim 21, wherein,
the gas supply tube is located on the vertical line of the line connecting between the first electrode and the second electrode.

25. The furnace tube for plasma enhanced thin film deposition according to claim 23, wherein,
a part of the inner wall of the process tube constitutes a first inner side wall of the ionization chamber, the ionization chamber further comprises a left side wall, a right side wall and a second inner side wall opposite to the first inner side wall, the same ends of the left side wall and the right side wall of the ionization chamber are connected to the first inner side wall respectively, and the other ends of the left side wall and the right side wall of the ionization chamber are connected to the second inner side wall respectively, so as to form the hollow ionization chamber along the axial direction of the process tube;
the first electrode and the second electrode are sequentially located on the same arc, the arc is located at the middle position between the second inner side wall and the first inner side wall, and the second electrode is located on the right side wall.

26. The furnace tube for plasma enhanced thin film deposition according to claim 24, wherein,
a part of the inner wall of the process tube constitutes a first inner side wall of the ionization chamber, the ionization chamber further comprises a left side wall, a right side wall and a second inner side wall opposite to the first inner side wall, the same ends of the left side wall and the right side wall of the ionization chamber are connected to the first inner side wall respectively, and the other ends of the ionization chamber are connected to the second inner side wall respectively, so as to form the hollow ionization chamber along the axial direction of the process tube;
the first electrode and the second electrode are sequentially located on the same arc line, the arc line is located at the middle position between the second inner side wall and the first inner side wall, the gas supply tube is close to the side of the first inner side wall, and the gas supply tube and the first gas holes are both located on the vertical line of the line connecting between the first electrode and the second electrode.

27. The furnace tube for plasma enhanced thin film deposition according to claim 26, wherein,
the gas supply tube is located outside the radius of the process tube, and the process tube is configured along the axial direction with the convex groove structure for accommodating the gas supply tube.

28. The furnace tube for plasma enhanced thin film deposition according to claim 25, wherein,
a baffle plate is connected between the first electrode and the second inner side wall, the baffle plate is perpendicular to the second inner side wall or forms the acute angle with the second inner side wall, the first gas holes are located between the baffle plate and the right side wall;
the right side wall is parallel to the baffle plate, or the part of the right side wall located between the second electrode and the first inner side wall forms the acute angle with the inner wall of the process tube, and the part of the right side wall located between the second electrode and the second inner side wall forms the acute angle with the second inner side wall.

29. The furnace tube for plasma enhanced thin film deposition according to claim 22, wherein,
the part of the inner wall of the process tube constitutes the first inner side wall of the ionization chamber, the ionization chamber further comprises the left side wall, the right side wall and the second inner side wall opposite to the first inner side wall, the same ends of the left side wall and the right side wall of the ionization chamber are connected to the first inner side wall respectively, and the other ends of the left side wall and the right side wall of the ionization chamber are connected to the second inner side wall respectively, so as to form the hollow ionization chamber along the axial direction of the process tube;
the first electrode and the second electrode are sequentially located on the same arc line, the arc line is located at the middle position of the second inner side wall and the first inner side wall, the gas supply tube is close to the side of the inner wall of the process tube, and the gas supply tube and the first gas hole are both located on the vertical line of the line connecting between the first electrode and the second electrode.

30. The furnace tube for plasma enhanced thin film deposition according to claim 29, wherein,
the left side wall and the right side wall are parallel to each other;
or the parts of the left side wall and the right side wall located between the first electrode and the second electrode and the first inner side wall are inclined in opposite directions, and the parts located between the first electrode and the second electrode and the second inner side wall are parallel to each other;
or the parts of the left side wall and the right side wall located between the first electrode and the second electrode and the first inner side wall are parallel to each other, and the parts located between the first electrode and the second electrode and the second inner side wall are inclined in opposite directions;
or the parts of the left side wall and the right side wall located between the first electrode and the second electrode and the first inner side wall, and the parts located between the first electrode and the second electrode and the second inner side wall are both inclined in opposite directions.

31. The furnace tube for plasma enhanced thin film deposition according to claim 18, wherein,
the flow area ratio of the gas supply tube to the second gas holes is in the range of 1: (0.21-0.48).
